(19) United States
(12) Patent Application Publication
(10) Pub. No.: US 2025/0029902 A1
(43) Pub. Date: Jan. 23, 2025

(54) LEAD FRAME AND MANUFACTURING METHOD OF SEMICONDUCTOR DEVICE

(71) Applicant: REALTEK SEMICONDUCTOR CORP., Hsinchu (TW)

(72) Inventor: Nai-Jen Hsuan, Hsinchu (TW)

(73) Assignee: REALTEK SEMICONDUCTOR CORP., Hsinchu (TW)

(21) Appl. No.: 18/632,966

(22) Filed: Apr. 11, 2024

(30) Foreign Application Priority Data
Jul. 17, 2023 (TW) 112126615

(51) Int. Cl. H01L 23/495; H01L 21/48; H01L 23/00

(52) U.S. Cl. CPC H01L 23/49541; H01L 21/4821; H01L 23/49548; H01L 23/49558; H01L 23/49589; H01L 24/11; H01L 24/16; H01L 24/17; H01L 24/81; H01L 23/49568; H01L 2224/113; H01L 2224/11849; H01L 2224/1601; H01L 2224/16258; H01L 2224/1703; H01L 2224/81815; H01L 2924/3011

(57) ABSTRACT

A lead frame adapted to be applied to a quad flat no-lead (QFN) package structure is provided. The QFN package structure includes a die. Bumps are disposed on an active surface of the die. The lead frame includes a central region and a peripheral region surrounding the central region. The lead frame includes a plurality of leads. The leads are at the peripheral region. A solder pad is disposed on an upper surface of one of two ends of each of the leads. The solder pad of each of the leads is configured to be directly soldered to a corresponding one of the bumps on the active surface of the die. For each of the leads, the end having the solder pad is nearer to the central region of the lead frame with respect to the other end. A manufacturing method of semiconductor device is also provided.

### CROSS-REFERENCE TO RELATED APPLICATION

This non-provisional application claims priority under 35 U.S.C. § 119 (a) to Patent Application No. 112126615 filed in Taiwan, R.O.C. on Jul. 17, 2023, the entire contents of which are hereby incorporated by reference.

### BACKGROUND

### Technical Field

The instant disclosure relates to the design of a lead frame used in flip-chip, and in particular relates to a lead frame and semiconductor device adapted to be applied to a quad flat no-lead (QFN) package structure.

### Related Art

A quad flat no-lead (QFN) package known to the inventor is a wire-bonded lead frame package, and the signal integrity and power integrity of the QFN packages are limited due to the impedance of the wire and internal leads. The longer the wire length is, the greater the impedance is. Therefore, in high-speed signal applications with high signal integrity and power integrity requirements, the QFN packages often have design difficulties due to excessive wire length. As a result, most current chip packages containing high-speed signals are still ball grid array (BGA) packages or flip chip packages which are considered to have better signal integrity and power integrity.

However, the lead frame of the quad flat no-lead (QFN) package known to the inventor provides a low-cost advantage compared to the substrate of the BGA package or the flip chip package. Moreover, when the die is bonded to the lead frame provided with an exposed metal pad, the heat can be dissipated directly through the large area of the exposed metal pad. Therefore, the heat dissipation effect of the QFN package is also better than that of other packaging methods. Furthermore, the substrates which can be used for BGA packages or flip chip packages are often in the condition of demand exceeds supply.

### SUMMARY

In one or some embodiments, a lead frame is adapted to be applied to a quad flat no-lead (QFN) package structure. The QFN package structure comprises a die. A plurality of bumps is disposed on an active surface of the die. The lead frame comprises a central region and a peripheral region surrounding the central region. The lead frame comprises a plurality of leads. A plurality of leads is at the peripheral region. A solder pad is disposed on an upper surface of one of two ends of each of the leads. The solder pad of each of the leads is configured to be directly soldered to a corresponding one of the bumps on the active surface of the die. For each of the leads, the end having the solder pad is nearer to the central region of the lead frame with respect to the other end.

In one or some embodiments, a lead frame is adapted to be applied to a QFN package structure. The QFN package structure comprises a die. A plurality of bumps is disposed on an active surface of the die. The lead frame comprises a central region and a peripheral region surrounding the central region. The lead frame comprises a plurality of leads. A plurality of leads is at the peripheral region. A solder pad is disposed on an upper surface of one of two ends of each of the leads. The solder pad of each of the leads is configured to be directly soldered to a corresponding one of the bumps on the active surface of the die. For each of the leads, the end having the solder pad is nearer to the central region of the lead frame with respect to the other end. The solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the first solder pads is greater than a height of any of the second solder pads. A height of any of the first bumps is less than a height of any of the second bumps.

In one or some embodiments, a semiconductor device comprises a die, a lead frame and a package. A plurality of bumps is disposed on an active surface of the die. The lead frame comprises a central region and a peripheral region surrounding the central region. The lead frame comprises a plurality of leads. A plurality of leads is at the peripheral region. A solder pad is disposed on an upper surface of one of two ends of each of the leads. The solder pad of each of the leads is configured to be directly soldered to a corresponding one of the bumps on the active surface of the die. For each of the leads, the end having the solder pad is nearer to the central region of the lead frame with respect to the other end. The package is configured to enclose the die and the lead frame.

In one or some embodiments, a semiconductor device comprises a die, a lead frame and a package. A plurality of bumps is disposed on an active surface of the die. The lead frame comprises a central region and a peripheral region surrounding the central region. The lead frame comprises a plurality of leads. A plurality of leads is at the peripheral region. A solder pad is disposed on an upper surface of one of two ends of each of the leads. The solder pad of each of the leads is configured to be directly soldered to a corresponding one of the bumps on the active surface of the die. For each of the leads, the end having the solder pad is nearer to the central region of the lead frame with respect to the other end. The package is configured to enclose the die and the lead frame. The solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the first solder pads is greater than a height of any of the second solder pads. A height of any of the first bumps is less than a height of any of the second bumps.

In one or some embodiments, a manufacturing method of semiconductor device comprises: (a) providing a lead frame, wherein the lead frame comprises a central region and a peripheral region surrounding the central region, the lead frame comprises a plurality of leads, and the leads are at the peripheral region; (b) providing a die, wherein the die comprises an active surface; (c) forming a plurality of bumps on the active surface of the die; (d) forming a solder pad on an upper surface of one of two ends of each of the leads, wherein for each of the leads, the end having the solder pad is nearer to the central region of the lead frame with respect to the other end; (e) contacting the bumps to the corresponding solder pads; and (f) performing a reflow procedure so that each of the solder pads is directly soldered to a corresponding one of the bumps.

In one or some embodiments, a manufacturing method of semiconductor device comprises: (a) providing a lead frame, wherein the lead frame comprises a central region and a peripheral region surrounding the central region, the lead frame comprises a plurality of leads, and the leads are at the peripheral region; (b) providing a die, wherein the die comprises an active surface; (c) forming a plurality of bumps on the active surface of the die; (d) forming a solder pad on an upper surface of one of two ends of each of the leads, wherein for each of the leads, the end having the solder pad is nearer to the central region of the lead frame with respect to the other end; (e) contacting the bumps to the corresponding solder pads; and (f) performing a reflow procedure so that each of the solder pads is directly soldered to a corresponding one of the bumps. The solder pads comprise a plurality of first solder pads and a plurality of second solder pads. The bumps comprise a plurality of first bumps and a plurality of second bumps. A height of any of the first solder pads is greater than a height of any of the second solder pads. A height of any of the first bumps is less than a height of any of the second bumps. In the step (e), each of the first bumps corresponds to a corresponding one of the first solder pads, and each of the second bumps corresponds to a corresponding one of the second solder pads. In the step (f), each of the first solder pads is directly soldered to a corresponding one of the first bumps, and each of the second solder pads is directly soldered to a corresponding one of the second bumps.

In one or some embodiments, a lead frame is adapted to be applied to a quad flat no-lead (QFN) package structure. The QFN package structure comprises a die. A plurality of bumps is disposed on an active surface of the die. The lead frame comprises a central region and a peripheral region surrounding the central region. The lead frame comprises a die-bonding region and a plurality of leads. The die-bonding region is at the central region. The die-bonding region comprises a metal layer and an insulation layer. The insulation layer is disposed on the metal layer. A plurality of leads is at the peripheral region. One of two ends of each of the leads is disposed on the insulation layer. A solder pad is disposed on an upper surface of one of two ends of each of the leads. The solder pad of each of the leads is configured to be directly soldered to a corresponding one of the bumps on the active surface of the die.

In one or some embodiments, a lead frame is adapted to be applied to a quad flat no-lead (QFN) package structure. The QFN package structure comprises a die. A plurality of bumps is disposed on an active surface of the die. The lead frame comprises a central region and a peripheral region surrounding the central region. The lead frame comprises a die-bonding region and a plurality of leads. The die-bonding region is at the central region. The die-bonding region comprises a metal layer and an insulation layer. The insulation layer is disposed on the metal layer. A plurality of leads is at the peripheral region. One of two ends of each of the leads is disposed on the insulation layer. A solder pad is disposed on an upper surface of one of two ends of each of the leads. The solder pad of each of the leads is configured to be directly soldered to a corresponding one of the bumps on the active surface of the die. The solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the first solder pads is greater than a height of any of the second solder pads. A height of any of the first bumps is less than a height of any of the second bumps.

In one or some embodiments, a lead frame is adapted to be applied to a quad flat no-lead (QFN) package structure. The QFN package structure comprises a die. A plurality of bumps is disposed on an active surface of the die. The lead frame comprises a central region and a peripheral region surrounding the central region. The lead frame comprises a die-bonding region and a plurality of leads. The die-bonding region is at the central region. The die-bonding region comprises a metal layer and an insulation layer. The insulation layer is disposed on the metal layer. A plurality of leads is at the peripheral region. One of two ends of each of the leads is disposed on the insulation layer. A solder pad is disposed on an upper surface of one of two ends of each of the leads. The solder pad of each of the leads is configured to be directly soldered to a corresponding one of the bumps on the active surface of the die. The solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the first solder pads is greater than a height of any of the second solder pads. A height of any of the first bumps is less than a height of any of the second bumps. The lead frame further comprises a plurality of metal traces and a capacitor. Each of the metal traces is coupled to one of the bumps. The capacitor is disposed on the insulation layer and is coupled between two adjacent metal traces.

In one or some embodiments, a semiconductor device comprises a die, a lead frame and a package. A plurality of bumps is disposed on an active surface of the die. The lead frame comprises a central region and a peripheral region surrounding the central region. The lead frame comprises a die-bonding region and a plurality of leads. The die-bonding region is at the central region. The die-bonding region comprises a metal layer and an insulation layer. The insulation layer is disposed on the metal layer. A plurality of leads is at the peripheral region. One of two ends of each of the leads is disposed on the insulation layer. A solder pad is disposed on an upper surface of one of two ends of each of the leads. The solder pad of each of the leads is configured to be directly soldered to a corresponding one of the bumps on the active surface of the die. The package is configured to enclose the die and the lead frame.

In one or some embodiments, a semiconductor device comprises a die, a lead frame and a package. A plurality of bumps is disposed on an active surface of the die. The lead frame comprises a central region and a peripheral region surrounding the central region. The lead frame comprises a die-bonding region and a plurality of leads. The die-bonding region is at the central region. The die-bonding region comprises a metal layer and an insulation layer. The insulation layer is disposed on the metal layer. A plurality of leads is at the peripheral region. One of two ends of each of the leads is disposed on the insulation layer. A solder pad is disposed on an upper surface of one of two ends of each of the leads. The solder pad of each of the leads is configured to be directly soldered to a corresponding one of the bumps on the active surface of the die. The package is configured to enclose the die and the lead frame. The solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the first solder pads is greater than a height of any of the second solder pads. A height of any of the first bumps is less than a height of any of the second bumps.

In one or some embodiments, a semiconductor device comprises a die, a lead frame and a package. A plurality of bumps is disposed on an active surface of the die. The lead frame comprises a central region and a peripheral region surrounding the central region. The lead frame comprises a die-bonding region and a plurality of leads. The die-bonding region is at the central region. The die-bonding region comprises a metal layer and an insulation layer. The insulation layer is disposed on the metal layer. A plurality of leads is at the peripheral region. One of two ends of each of the leads is disposed on the insulation layer. A solder pad is disposed on an upper surface of one of two ends of each of the leads. The solder pad of each of the leads is configured to be directly soldered to a corresponding one of the bumps on the active surface of the die. The package is configured to enclose the die and the lead frame. The solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the first solder pads is greater than a height of any of the second solder pads. A height of any of the first bumps is less than a height of any of the second bumps. The lead frame further comprises a plurality of metal traces and a capacitor. Each of the metal traces is coupled to one of the bumps. The capacitor is disposed on the insulation layer and is coupled between two adjacent metal traces.

In one or some embodiments, a manufacturing method of semiconductor device comprises: (a) providing a lead frame, wherein the lead frame comprises a central region and a peripheral region surrounding the central region, the lead frame comprises a die-bonding region and a plurality of leads, the die-bonding region is at the central region, the die-bonding region comprises a metal layer, and the leads are at the peripheral region; (b) disposing an insulation layer on the metal layer, wherein one of two ends of each of the leads is disposed on the insulation layer; (c) providing a die, wherein the die comprises an active surface; (d) forming a plurality of bumps on the active surface of the die; (e) forming a solder pad on an upper surface of the end of each of the leads disposed on the insulation layer; (f) contacting the bumps to the corresponding solder pads; and (g) performing a reflow procedure so that each of the solder pads is directly soldered to a corresponding one of the bumps.

In one or some embodiments, a manufacturing method of semiconductor device comprises: (a) providing a lead frame, wherein the lead frame comprises a central region and a peripheral region surrounding the central region, the lead frame comprises a die-bonding region and a plurality of leads, the die-bonding region is at the central region, the die-bonding region comprises a metal layer, and the leads are at the peripheral region; (b) disposing an insulation layer on the metal layer, wherein one of two ends of each of the leads is disposed on the insulation layer; (c) providing a die, wherein the die comprises an active surface; (d) forming a plurality of bumps on the active surface of the die; (e) forming a solder pad on an upper surface of the end of each of the leads disposed on the insulation layer; (f) contacting the bumps to the corresponding solder pads; and (g) performing a reflow procedure so that each of the solder pads is directly soldered to a corresponding one of the bumps. The solder pads comprise a plurality of first solder pads and a plurality of second solder pads. The bumps comprise a plurality of first bumps and a plurality of second bumps. A height of any of the first solder pads is greater than a height of any of the second solder pads. A height of any of the first bumps is less than a height of any of the second bumps. In the step (f), each of the first bumps corresponds to a corresponding one of the first solder pads, and each of the second bumps corresponds to a corresponding one of the second solder pads. In the step (g), each of the first solder pads is directly soldered to a corresponding one of the first bumps, and each of the second solder pads is directly soldered to a corresponding one of the second bumps.

In some embodiments, a manufacturing method of semiconductor device comprises: (a) providing a lead frame, wherein the lead frame comprises a central region and a peripheral region surrounding the central region, the lead frame comprises a die-bonding region and a plurality of leads, the die-bonding region is at the central region, the die-bonding region comprises a metal layer, and the leads are at the peripheral region; (b) disposing an insulation layer on the metal layer, wherein one of two ends of each of the leads is disposed on the insulation layer; (c) providing a die, wherein the die comprises an active surface; (d) forming a plurality of bumps on the active surface of the die; (e) forming a solder pad on an upper surface of the end of each of the leads disposed on the insulation layer; (f) contacting the bumps to the corresponding solder pads; and (g) performing a reflow procedure so that each of the solder pads is directly soldered to a corresponding one of the bumps. The solder pads comprise a plurality of first solder pads and a plurality of second solder pads. The bumps comprise a plurality of first bumps and a plurality of second bumps. A height of any of the first solder pads is greater than a height of any of the second solder pads. A height of any of the first bumps is less than a height of any of the second bumps. In the step (f), each of the first bumps corresponds to a corresponding one of the first solder pads, and each of the second bumps corresponds to a corresponding one of the second solder pads. In the step (g), each of the first solder pads is directly soldered to a corresponding one of the first bumps, and each of the second solder pads is directly soldered to a corresponding one of the second bumps. The manufacturing method of semiconductor device further comprises: (h) forming a plurality of metal traces on the insulation layer, wherein each of the metal traces is coupled to one of the bumps; and (i) disposing a capacitor on the insulation layer, wherein the capacitor is coupled between two adjacent metal traces.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The instant disclosure will become more fully understood from the detailed description given herein below for illustration only, and thus not limitative of the instant disclosure, wherein:

FIG. 1 illustrates a top view of an embodiment of a lead frame;

FIG. 2 illustrates a cross-sectional view of the lead frame along the sectional line 100 shown in FIG. 1;

FIG. 3 illustrates a cross-sectional view of an embodiment of the lead frame and a die;

FIG. 4 illustrates an exploded view of an embodiment of the lead frame and the die;

FIG. 5 illustrates a top view of another embodiment of the lead frame;

FIG. 6 illustrates a cross-sectional view of the lead frame along the sectional line 200 shown in FIG. 5;

FIG. 7 illustrates a cross-sectional view of another embodiment of the lead frame and the die;

FIG. 8 illustrates a bottom view of an embodiment of the die;

FIG. 9 illustrates a schematic view of an embodiment of a semiconductor device;

FIG. 10 illustrates a flow chart of an embodiment of a manufacturing method of semiconductor device;

FIG. 11 illustrates a top view of yet another embodiment of the lead frame;

FIG. 12A illustrates a cross-sectional view of the lead frame along the sectional line 300 shown in FIG. 11;

FIG. 12B illustrates a cross-sectional view of the lead frame along sectional line 400 shown in FIG. 11;

FIG. 13A illustrates a cross-sectional view of yet another embodiment of the lead frame and the die;

FIG. 13B illustrates another cross-sectional view of yet another embodiment of the lead frame and the die;

FIG. 14 illustrates a top view of a further embodiment of the lead frame;

FIG. 15 illustrates a schematic view of another embodiment of the semiconductor device; and

FIG. 16 illustrates a flow chart of another embodiment of a method of the manufacturing method of semiconductor device.

### DETAILED DESCRIPTION

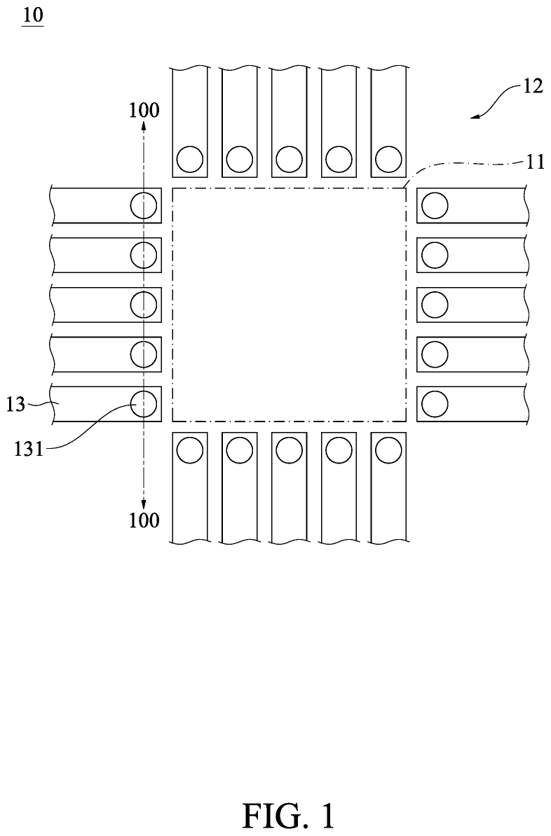

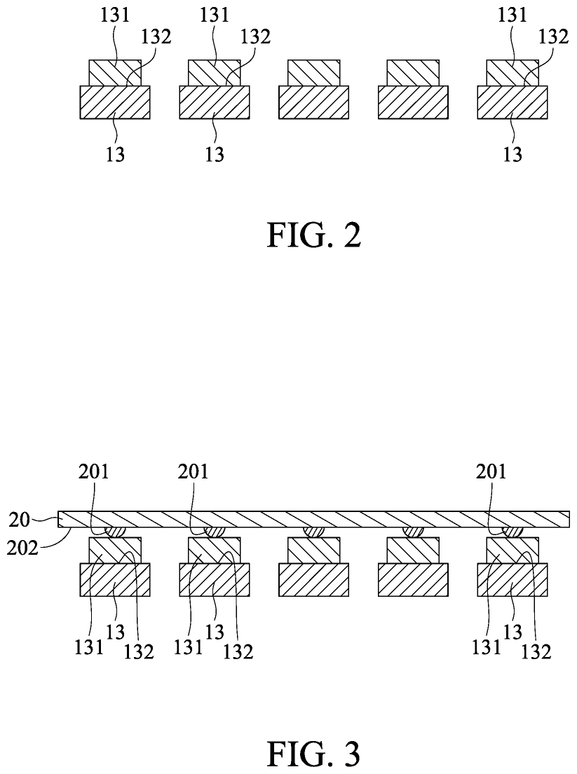

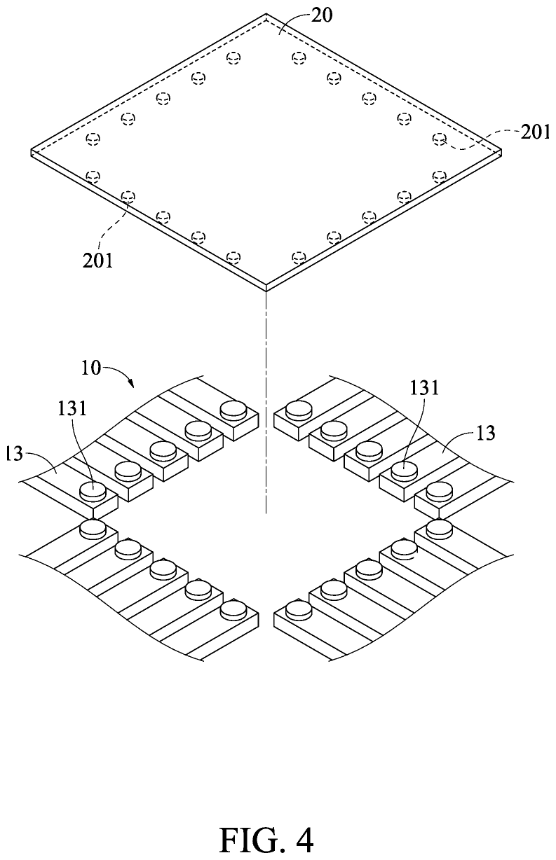

FIG. 1 illustrates a top view of an embodiment of a lead frame 10. FIG. 2 illustrates a cross-sectional view of the lead frame 10 along the sectional line 100 shown in FIG. 1. FIG. 3 illustrates a cross-sectional view of an embodiment of the lead frame 10 and a die 20. FIG. 4 illustrates an exploded view of an embodiment of the lead frame 10 and the die 20. Please refer to FIG. 1 to FIG. 4. A lead frame 10 is adapted to be applied to a quad flat no-lead (QFN) package structure. The QFN package structure comprises a die 20. A plurality of bumps 201 is disposed on an active surface 202 of the die. The lead frame 10 comprises a central region 11 and a peripheral region 12 surrounding the central region 11. The lead frame 10 comprises a plurality of leads 13. The plurality of leads 13 is at the peripheral region 12. A solder pad 131 is disposed on an upper surface 132 of one of two ends of each of the leads 13. The solder pad 131 of each of the leads 13 is configured to be directly soldered to a corresponding one of the bumps 201 on the active surface 202 of the die 20. For each of the leads 13, the end having the solder pad 131 is nearer to the central region 11 of the lead frame 10 with respect to the other end. That is, for each of the leads 13, a distance between the end having the solder pad 131 and the central region 11 of the lead frame 10 is less than a distance between the other end and the central region 11 of the lead frame 10. In some embodiments, the plurality of bumps 201 is disposed on the periphery of the active surface 202, but the instant disclosure is not limited thereto. The plurality of bumps 201 can be disposed at any position on the active surface 202. The shape of the bump 201 and the shape of the solder pad 131 are not limited in the instant disclosure.

In some embodiments, the solder pad 131 of each of the leads 13 is directly soldered to a corresponding one of the bumps 201 on the active surface 202 of the die 20 along a vertical direction, but the instant disclosure is not limited thereto. In some embodiments, the solder pad 131 may be but not limited to a solder ball. In some embodiments, the solder pad 131 may be but not limited to be disposed on an upper surface 132 of one of two ends of each of the leads 13 by electroplating, and the material of the solder pad 131 may be but not limited to copper, aluminum, or tin. In some embodiments, the position of the solder pad 131 on the upper surface 132 of one of two ends of each of the leads 13 may be but not limited to be determined through automated optical inspection (AOI) such as 3D AOI or 2D AOI. In some embodiments, the size of each of the solder pads 131 is identical.

In some embodiments, the bump 201 may be but not limited to a solder ball or a copper pillar. In some embodiments, the bump 201 may be but not limited to be disposed on the active surface 202 of the die 20 by ball mounting, solder paste printing, or electroplating. In some embodiments, the bump 201 may be but not limited to be eutectically bonded to the solder pad 131. In some embodiments, the size of each of the bumps 201 is identical. In some embodiments, the plurality of bumps 201 is configured to transmit high-speed signals, but the instant disclosure is not limited thereto. The plurality of bumps 201 can also be configured to transmit low-speed signals.

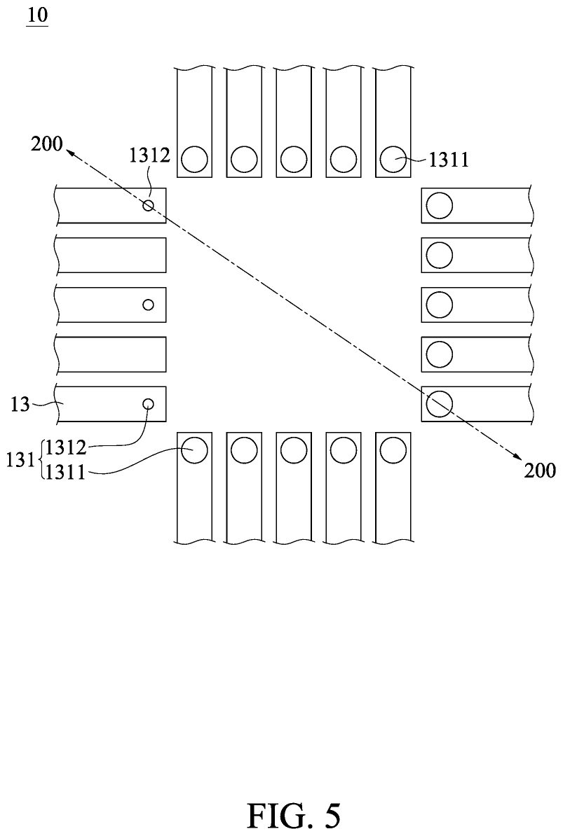

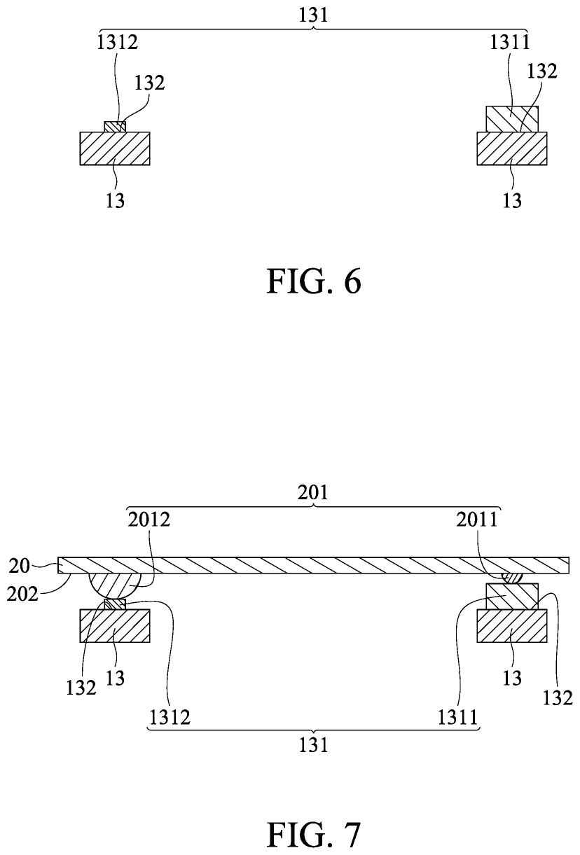

FIG. 5 illustrates a top view of another embodiment of the lead frame 10. FIG. 6 illustrates a cross-sectional view of the lead frame 10 along the sectional line 200 shown in FIG. 5. FIG. 7 illustrates a cross-sectional view of another embodiment of the lead frame 10 and the die 20. Please refer to FIG. 5 to FIG. 7. In some embodiments, the plurality of solder pads 131 comprises a plurality of first solder pads 1311 and a plurality of second solder pads 1312. The plurality of bumps 201 comprises a plurality of first bumps 2011 and a plurality of second bumps 2012. The size of the plurality of first solder pads 1311 is greater than the size of the plurality of second bonding pads 1312, and the size of the plurality of first bumps 2011 is less than the size of the plurality of second bumps 2012. That is, in some embodiments, the width and height of the plurality of first solder pads 1311 are respectively greater than the width and height of the plurality of second solder pads 1312, and the width and height of the plurality of first bumps 2011 are respectively less than the width and height of the plurality of second bumps 2012. In order to ensure that all the bumps 201 can be successfully soldered to the respective solder pads 131 at the same time and take the balance issue between the lead frame 10 and the die 20 after the plurality of bumps 201 is soldered to the plurality of solder pads 131 into consideration, each of the first solder pads 1311 is configured to be directly soldered to a corresponding one of the first bumps 2011 and each of the second solder pads 1312 is configured to be directly soldered to a corresponding one of the second bumps 2012.

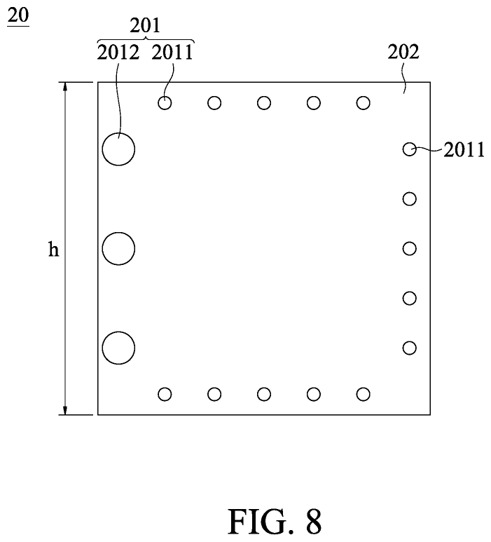

In some embodiments, because the size of the first bump 2011 is different from the size of the second bump 2012, under a same side length h of the die 20, the number of the first bumps 2011 that can be disposed on the active surface 202 of the die will also be different from the number of the second bumps 2012 that can be disposed on the active surface 202 of the die. Please refer to FIG. 5 and FIG. 8. For example, assume that the side length h of the left side of the die 20 and the side length h of the right side of the die 20 shown in FIG. 8 are equal, because the size of the plurality of first bumps 2011 is less than the size of the plurality of second bumps 2012, five first bumps 2011 can be disposed on the right side of the die 20 while only three second bumps 2012 can be disposed on the left side of the die 20. The lead frame 10 which is connected to the die 20 shown in FIG. 8 is the lead frame 10 shown in FIG. 5. In order to correspond to the positions of the plurality of second bumps 2012 of the die 20 shown in FIG. 8, in some embodiments, only three of the plurality of leads 13 on the left side of the lead frame 10 are provided with the second solder pads 1312, and two of the plurality of leads 13 on the left side of the lead frame 10 are not provided with the solder pads 131. In other words, in some embodiments, not all the upper surfaces 132 of the leads 13 are provided with the solder pads 131.

In some embodiments, the plurality of second bumps 2012 are disposed in the middle portion of the active surface 202, but the instant disclosure is not limited thereto. Since the size of the second bump 2012 is greater than the size of the first bump 2011, it is more convenient for the current of the die 20 to flow out from the second bump 2012. Therefore, in some embodiments, the plurality of second bumps 2012 are configured to transmit power signals, but the instant disclosure is not limited thereto. The plurality of second bumps 2012 can also be configured to transmit differential signals or ground signals. In some embodiments, the plurality of first bumps 2011 may be but not limited to be configured to transmit differential signals or ground signals.

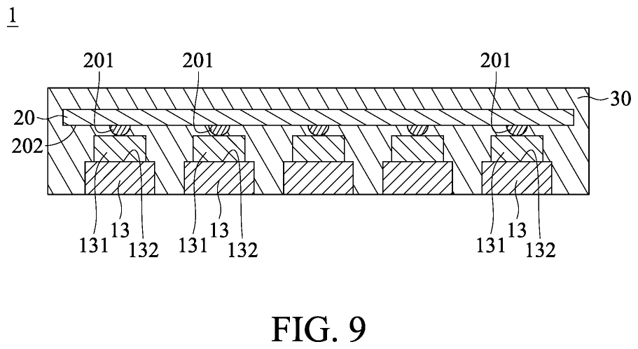

FIG. 9 illustrates a schematic view of an embodiment of a semiconductor device 1. Please refer to FIG. 9. The semiconductor device 1 comprises a die 20, a lead frame 10, and a package 30. A plurality of bumps 201 is disposed on an active surface 202 of the die 20. The lead frame 10 comprises a central region 11 and a peripheral region 12 surrounding the central region 11. The lead frame 10 comprises a plurality of leads 13. The plurality of leads 13 is at the peripheral region 12. A solder pad 131 is disposed on an upper surface 132 of one of two ends of each of the leads 13. The solder pad 131 of each of the leads 13 is configured to be directly soldered to a corresponding one of the bumps 201 on the active surface 202 of the die 20. For each of the leads 13, the end having the solder pad 131 is nearer to the central region 11 of the lead frame 10 with respect to the other end. That is, for each of the leads 13, a distance between the end having the solder pad 131 and the central region 11 of the lead frame 10 is less than a distance between the other end and the central region 11 of the lead frame 10. The package 30 is configured to enclose the die 20 and the lead frame 10.

In some embodiments, the lead frame 10 may have the distribution position or the distribution number of the plurality of leads 13 on one of the sides different from the distribution position or the distribution number of the plurality of leads 13 on the other sides to allow the user to identify the direction in which the lead frame 10 and the semiconductor device 1 including the lead frame 10 are disposed.

The purpose of enclosing the die 20 and the lead frame 10 through the package 30 is to prevent air and moisture from entering the die 20 and the lead frame 10. In some embodiments, the package 30 encloses the die 20 by covering all portions of the die 20, but the instant disclosure is not limited thereto. The package 30 may also enclose the die 20 by only covering the edge of the die 20. In some embodiments, the material of the package 30 may be selected according to the impedance system applied in the semiconductor device 1. In some embodiments, the material of the package 30 may be but not limited to common epoxy resin packaging material or aluminum oxide epoxy resin packaging material.

In some embodiments, the lead frame 10 included in the semiconductor device 1 is the lead frame 10 shown in FIG. 5. The plurality of solder pads 131 of the lead frame 10 comprises a plurality of first solder pads 1311 and a plurality of second solder pads 1312. The plurality of bumps 201 comprises a plurality of first bumps 2011 and a plurality of second bumps 2012. The size of the plurality of first solder pads 1311 is greater than the size of the plurality of second bonding pads 1312, and the size of the plurality of first bumps 2011 is less than the size of the plurality of second bumps 2012. Each of the first solder pads 1311 is configured to be directly soldered to a corresponding one of the first bumps 2011 and each of the second solder pads 1312 is configured to be directly soldered to a corresponding one of the second bumps 2012.

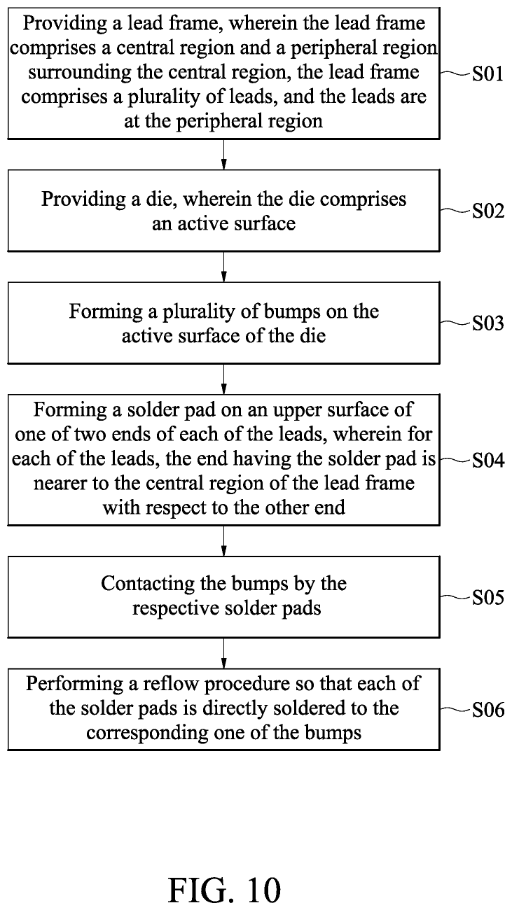

FIG. 10 illustrates a flow chart of an embodiment of a manufacturing method of semiconductor device 1. Please refer to FIG. 10. First, a lead frame 10 is provided (step S01) and a die 20 is provided (step S02). The lead frame 10 comprises a central region 11 and a peripheral region 12 surrounding the central region 11. The lead frame comprises a plurality of leads 13, and the plurality of leads 13 is at the peripheral region 12. The die 20 comprises an active surface 202. Then, a plurality of bumps 201 is formed on the active surface 202 of the die 20 (step S03). Next, a solder pad 131 is formed on an upper surface 132 of one of two ends of each of the leads 13 (step S04). For each of the leads 13, the end having the solder pad 131 is nearer to the central region 11 of the lead frame 10 with respect to the other end. Last, the plurality of bumps 201 is contacted by the respective solder pads 131 (step S05) and a reflow procedure is performed so that each of the solder pads 131 is directly soldered to the corresponding one of the bumps 201 (step S06).

In some embodiments, the plurality of solder pads 131 of the lead frame 10 comprises a plurality of first solder pads 1311 and a plurality of second solder pads 1312. The plurality of bumps 201 comprises a plurality of first bumps 2011 and a plurality of second bumps 2012. The size of the plurality of first solder pads 1311 is greater than the size of the plurality of second bonding pads 1312, and the size of the plurality of first bumps 2011 is less than the size of the plurality of second bumps 2012. In some embodiments, in the step S05, each of the first bumps 2011 corresponds to a corresponding one of the first solder pads 1311, and each of the second bumps 2012 corresponds to a corresponding one of the second solder pads 1312. In the step S06, each of the first solder pads 1311 is directly soldered to the corresponding one of the first bumps 2011, and each of the second solder pads 1312 is directly soldered to the corresponding one of the second bumps 2012.

In some embodiments, the manufacturing method of the semiconductor device 1 further comprises forming a package 30 to enclose the die 20 and the lead frame 10 after step S06. In some embodiments, the manufacturing method of the semiconductor device 1 further comprises immersing the tops of the plurality of bumps 201 into a flux so that the flux is adhered to the plurality of bumps 201 before step S05.

In some embodiments, detail steps of step S03 are described as below. First, a photoresist layer is formed on the active surface 202 of the die 20. Then, a plurality of first openings and a plurality of second openings are formed on the photoresist layer, wherein the opening area of any of the plurality of first openings is less than the opening area of any of the plurality of second openings. Then, a metal is filled into the plurality of first openings and the plurality of second openings. Next, the photoresist layer is removed. Last, the reflow procedure is performed so that the metal in each of the first openings forms the corresponding one of the first bumps 2011 and the metal in each of the second openings forms the corresponding one of the second bumps 2012.

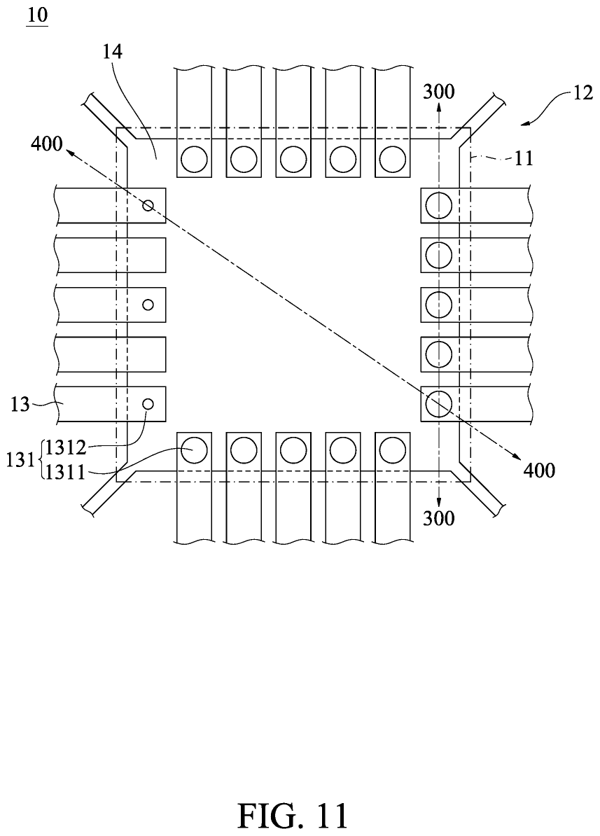

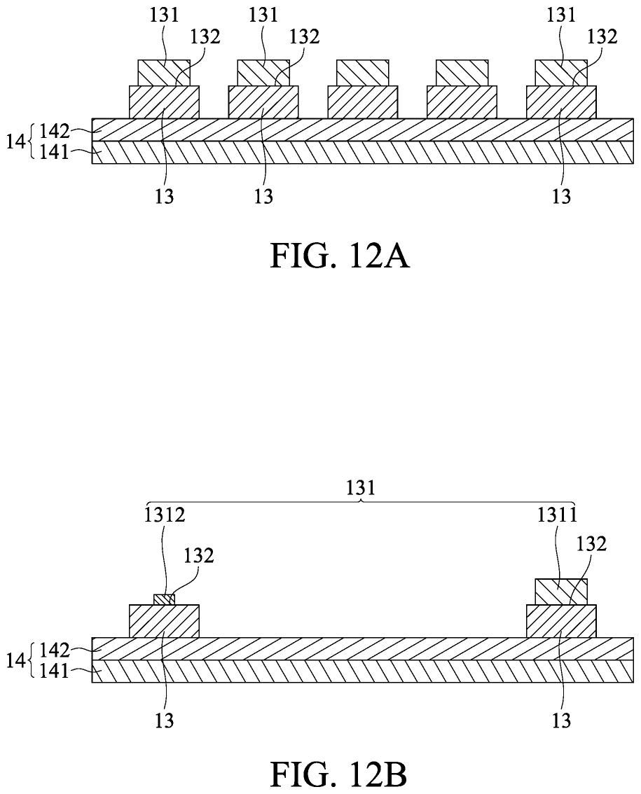

FIG. 11 illustrates a top view of yet another embodiment of the lead frame 10. FIG. 12A illustrates a cross-sectional view of the lead frame 10 along sectional line 300 shown in

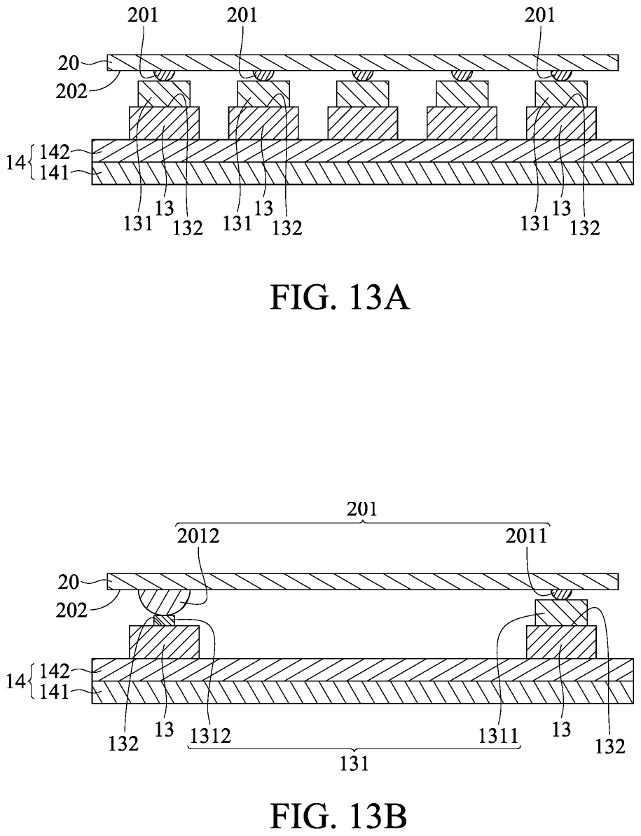

FIG. 11. FIG. 12B illustrates a cross-sectional view of the lead frame 10 along sectional line 400 shown in FIG. 11. FIG. 13A illustrates a cross-sectional view of yet another embodiment of the lead frame 10 and the die 20. FIG. 13B illustrates another cross-sectional view of yet another embodiment of the lead frame 10 and the die 20. Please refer to FIG. 11 to FIG. 13B. A lead frame 10 is adapted to be applied to a QFN package structure. The QFN package structure comprises a die 20. A plurality of bumps 201 is disposed on an active surface 202 of the die 20. The lead frame 10 comprises a central region 11 and a peripheral region 12 surrounding the central region 11. The lead frame 10 comprises a die-bonding region 14 and a plurality of leads 13. The die-bonding region is at the central region 11. The die-bonding region comprises a metal layer 141 and an insulation layer 142. The insulation layer 142 is disposed on the metal layer 141. The plurality of leads 13 is at the peripheral region 12. One of two ends of each of the leads 13 is disposed on the insulation layer 142. A solder pad 131 is disposed on an upper surface of one of two ends of each of the leads 13. The solder pad 131 of each of the leads 13 is configured to be directly soldered to a corresponding one of the bumps 201 on the active surface 202 of the die 20. In some embodiments, the metal layer 141 is an exposed metal pad (EPAD).

In some embodiments, the plurality of solder pads 131 comprises a plurality of first solder pads 1311 and a plurality of second solder pads 1312. The plurality of bumps 201 comprises a plurality of first bumps 2011 and a plurality of second bumps 2012. The size of the plurality of first solder pads 1311 is greater than the size of the plurality of second bonding pads 1312, and the size of the plurality of first bumps 2011 is less than the size of the plurality of second bumps 2012. That is, in some embodiments, the width and height of the plurality of first solder pads 1311 are respectively greater than the width and height of the plurality of second solder pads 1312, and the width and height of the plurality of first bumps 2011 are respectively less than the width and height of the plurality of second bumps 2012. Each of the first solder pads 1311 is configured to be directly soldered to a corresponding one of the first bumps 2011 and each of the second solder pads 1312 is configured to be directly soldered to a corresponding one of the second bumps 2012.

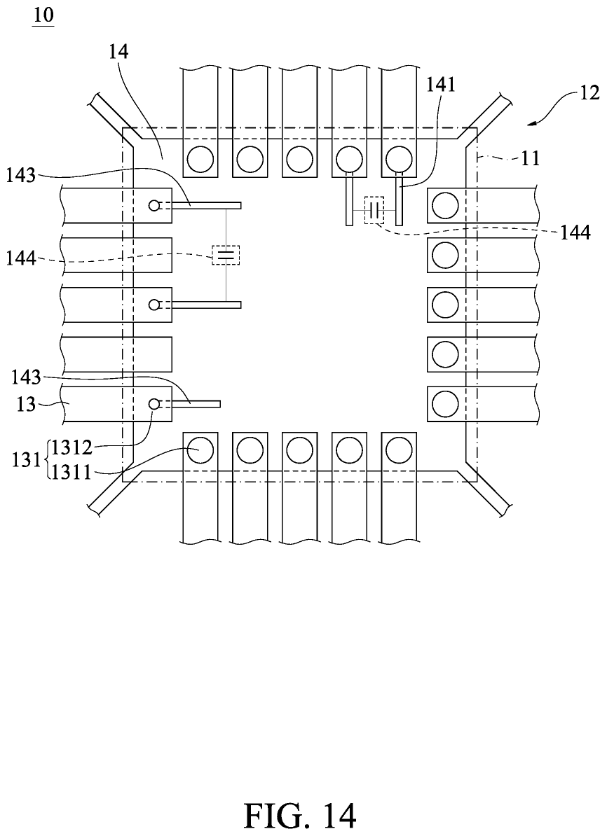

FIG. 14 illustrates a top view of a further embodiment of the lead frame 10. Please refer to FIG. 14. In some embodiments, the lead frame 10 further comprises a plurality of metal traces 143 and a capacitor 144. The plurality of metal traces 143 is disposed on the insulation layer 142, wherein each of the metal traces 143 is coupled to a corresponding one of the bumps 201. The capacitor 144 is disposed on the insulation layer 142, wherein the capacitor 144 is coupled between two adjacent metal traces 143. In some embodiments, the plurality of metal traces 143 is disposed directly under the die 20, but the instant disclosure is not limited thereto. In some embodiments, the plurality of metal traces 143 is not disposed directly under the die 20.

In some embodiments, the material of the metal trace 143 may be but not limited to copper. In some embodiments, the metal trace 143 may be but not limited to be disposed on the insulation layer 142 through a patterning process. In some embodiments, the patterning process comprises a coating process, an exposure process, and a development process. The length and shape of the metal trace 143 are not limited in the instant disclosure.

The purpose of disposing the capacitor 144 is to reduce the power ripple generated by the power signal of the die 20 after the die 20 is connected to the lead frame 10. In some embodiments, the capacitor 144 may be but not limited to be disposed on the insulation layer 142 through surface mount technology (SMT). In some embodiments, the capacitor 144 is disposed directly under the die 20, but the instant disclosure is not limited thereto. In some embodiments, the capacitor 144 is not disposed directly under the die 20.

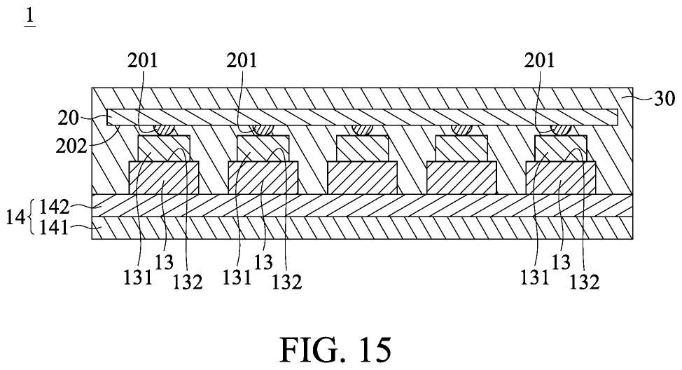

FIG. 15 illustrates a schematic view of another embodiment of the semiconductor device 1. Please refer to FIG. 15. The semiconductor device 1 comprises a die 20, a lead frame 10, and a package 30. A plurality of bumps 201 is disposed on an active surface 202 of the die 20. The lead frame 10 comprises a central region 11 and a peripheral region 12 surrounding the central region 11. The lead frame 10 comprises a die-bonding region 14 and a plurality of leads 13. The die-bonding region is at the central region 11. The die-bonding region comprises a metal layer 141 and an insulation layer 142. The insulation layer 142 is disposed on the metal layer 141. The plurality of leads 13 is at the peripheral region 12. One of two ends of each of the leads 13 is disposed on the insulation layer 142. A solder pad 131 is disposed on an upper surface of one of two ends of each of the leads 13. The solder pad 131 of each of the leads 13 is configured to be directly soldered to a corresponding one of the bumps 201 on the active surface 202 of the die 20. The package 30 is configured to enclose the die 20 and the lead frame 10.

In some embodiments, the shape of one of the corners of the die-bonding region 14 may be configured to be different from the shapes of other corners of the die-bonding region 14. For example, one of the corners of the die-bonding region 14 is a missing corner, but the other corners of the die-bonding region 14 are not missing corners, so that the user can identify the direction in which the lead frame 10 and the semiconductor device 1 including the lead frame 10 are disposed by observing the shape of the corner of the die-bonding region 14.

In some embodiments, the plurality of solder pads 131 of the lead frame 10 included in the semiconductor device 1 comprises a plurality of first solder pads 1311 and a plurality of second solder pads 1312. The plurality of bumps 201 comprises a plurality of first bumps 2011 and a plurality of second bumps 2012. The size of the plurality of first solder pads 1311 is greater than the size of the plurality of second bonding pads 1312, and the size of the plurality of first bumps 2011 is less than the size of the plurality of second bumps 2012. That is, the width and height of the plurality of first solder pads 1311 are respectively greater than the width and height of the plurality of second solder pads 1312, and the width and height of the plurality of first bumps 2011 are respectively less than the width and height of the plurality of second bumps 2012. Each of the first solder pads 1311 is configured to be directly soldered to a corresponding one of the first bumps 2011 and each of the second solder pads 1312 is configured to be directly soldered to a corresponding one of the second bumps 2012.

In some embodiments, the semiconductor device 1 further comprises a plurality of metal traces 143 and a capacitor 144. The plurality of metal traces 143 are disposed on the insulation layer 142, wherein each of the metal traces 143 is coupled to a corresponding one of the bumps 201. The capacitor 144 is disposed on the insulation layer 142, wherein the capacitor 144 is coupled between two adjacent metal traces 143.

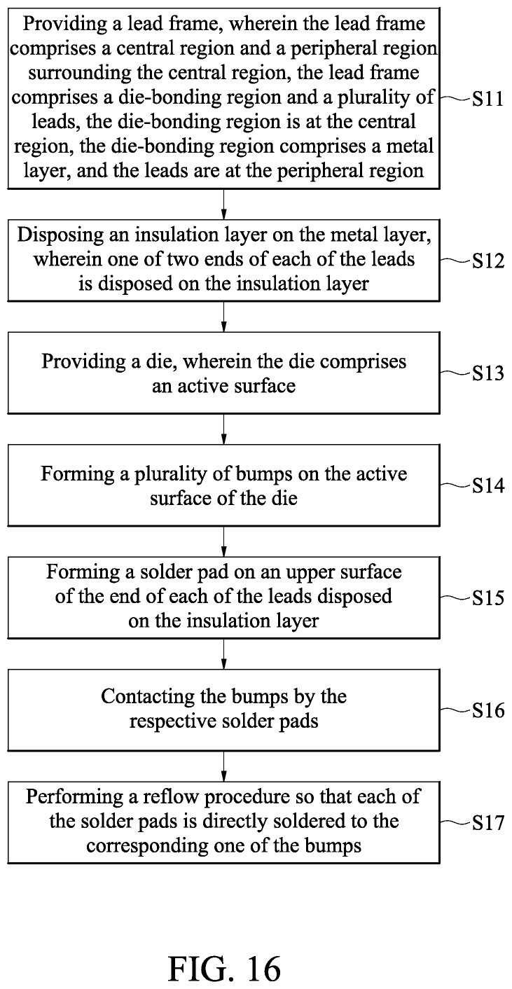

FIG. 16 illustrates a flow chart of another embodiment of a method of the manufacturing method of semiconductor device 1. Please refer to FIG. 16. First, a lead frame 10 is provided (step S11). The lead frame 10 comprises a central region 11 and a peripheral region 12 surrounding the central region 11. The lead frame 10 comprises a die-bonding region 14 and a plurality of leads 13. The die-bonding region 14 is at the central region 11. The die-bonding region 14 comprises a metal layer 141. The plurality of leads 13 is at the peripheral region 12. Then, an insulation layer 142 is disposed on the metal layer 141 (step S12), and one of two ends of each of the leads 13 is disposed on the insulation layer 142. Then, a die 20 is provided (step S13). The die 20 comprises an active surface 202. Next, a plurality of bumps 201 is formed on the active surface 202 of the die 20 (step S14). Furthermore, a solder pad 131 is formed on an upper surface 132 of the end of each of the leads 13 disposed on the insulation layer 142 (step S15). Last, the plurality of bumps 201 is contacted by the respective solder pads 131 (step S16) and a reflow procedure is performed, so that each of the solder pads 131 is directly soldered to the corresponding one of the bumps 201 (step S17).

In some embodiments, the insulation layer 142 is disposed on the metal layer 141 through chemical methods such as chemical vapor deposition or photoresist coating, but the instant disclosure is not limited thereto. The insulation layer 142 may also be disposed on the metal layer 141 through physical methods.

In some embodiments, the plurality of solder pads 131 of the lead frame 10 comprises a plurality of first solder pads 1311 and a plurality of second solder pads 1312. The plurality of bumps 201 comprises a plurality of first bumps 2011 and a plurality of second bumps 2012. The size of the plurality of first solder pads 1311 is greater than the size of the plurality of second bonding pads 1312, and the size of the plurality of first bumps 2011 is less than the size of the plurality of second bumps 2012. In some embodiments, in the step S16, each of the first bumps 2011 corresponds to a corresponding one of the first solder pads 1311, and each of the second bumps 2012 corresponds to a corresponding one of the second solder pads 1312. In some embodiments, in the step S17, each of the first solder pads 1311 is directly soldered to the corresponding one of the first bumps 2011, and each of the second solder pads 1312 is directly soldered to the corresponding one of the second bumps 2012.

In some embodiments, the manufacturing method of the semiconductor device 1 further comprises forming a plurality of metal traces 143 and a capacitor 144 on the insulation layer 142. Each of the metal traces 143 is coupled to a corresponding one of the bumps 201, and the capacitor 144 is coupled between two adjacent metal traces 143.

To sum up, in some embodiments, the lead frame 10 does not necessarily need to be connected to the die 20 through wire bonding like the QFN package known to the inventor; instead, the lead frame 10 is connected to the plurality of bumps 201 of the die 20 through the plurality of solder pads 131. Hence, the signal integrity and power integrity of the lead frame 10 are not limited by the impedance of the wire and internal leads. Therefore, the lead frame 10 can be applied to high-speed signal chip packaging. In some embodiments, according to user's demands, the lead frame 10 can be connected to the plurality of first bumps 2011 and the plurality of second bumps 2012 of different sizes disposed on the active surface 202 of the die 20 through the plurality of first solder pads 1311 and the plurality of second solder pads 1312. Therefore, after the lead frame 10 is connected to the die 20, imbalance issue caused by the different sizes of the plurality of first bumps 2011 and the plurality of second bumps 2012 does not occur.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A lead frame, adapted to be applied to a quad flat no-lead (QFN) package structure, the QFN package structure comprising a die, a plurality of bumps being disposed on an active surface of the die, and the lead frame comprising a central region and a peripheral region surrounding the central region, wherein the lead frame comprises:
a plurality of leads at the peripheral region, wherein a solder pad is disposed on an upper surface of one of two ends of each of the leads, and the solder pad of each of the leads is configured to be directly soldered to a corresponding one of the bumps on the active surface of the die; for each of the leads, the end having the solder pad is nearer to the central region of the lead frame with respect to the other end.

2. The lead frame according to claim 1, wherein the solder pads comprise a plurality of first solder pads and a plurality of second solder pads, the bumps comprise a plurality of first bumps and a plurality of second bumps, each of the first solder pads is configured to be directly soldered to a corresponding one of the first bumps, each of the second solder pads is configured to be directly soldered to a corresponding one of the second bumps, a height of any of the first solder pads is greater than a height of any of the second solder pads, and a height of any of the first bumps is less than a height of any of the second bumps.

3. A manufacturing method of semiconductor device, comprising:
(a) providing a lead frame, wherein the lead frame comprises a central region and a peripheral region surrounding the central region, the lead frame comprises a plurality of leads, and the leads are at the peripheral region;
(b) providing a die, wherein the die comprises an active surface;
(c) forming a plurality of bumps on the active surface of the die;
(d) forming a solder pad on an upper surface of one of two ends of each of the leads, wherein for each of the leads, the end having the solder pad is nearer to the central region of the lead frame with respect to the other end;
(e) contacting the bumps to the corresponding solder pads; and
(f) performing a reflow procedure so that each of the solder pads is directly soldered to a corresponding one of the bumps.

4. The manufacturing method of semiconductor device according to claim 3, wherein the bumps comprise a plurality of first bumps and a plurality of second bumps, and a height of any of the first bumps is less than a height of any of the second bumps, the solder pads comprise a plurality of first solder pads and a plurality of second solder pads, and a height of any of the first solder pads is greater than a height of any of the second solder pads.

5. The manufacturing method of semiconductor device according to claim 4, wherein in the step (e), each of the first bumps corresponds to a corresponding one of the first solder pads, and each of the second bumps corresponds to a corresponding one of the second solder pads.

6. The manufacturing method of semiconductor device according to claim 5, wherein in the step (f), each of the first solder pads is directly soldered to a corresponding one of the first bumps, and each of the second solder pads is directly soldered to a corresponding one of the second bumps.

7. The manufacturing method of semiconductor device according to claim 6, further comprising:
(g) forming a package to enclose the die and the lead frame.

8. The manufacturing method of semiconductor device according to claim 7, wherein the step (c) comprises:
forming a photoresist layer on the active surface of the die;
forming a plurality of first openings and a plurality of second openings on the photoresist layer, wherein an opening area of any of the first openings is less than an opening area of any of the second openings;
filling a metal into the first openings and the second openings;
removing the photoresist layer; and
performing a reflow procedure so that the metal in each of the first openings forms the corresponding one of the first bumps and the metal in each of the second openings forms the corresponding one of the second bumps.

9. A manufacturing method of semiconductor device, comprising:
(a) providing a lead frame, wherein the lead frame comprises a central region and a peripheral region surrounding the central region, the lead frame comprises a die-bonding region and a plurality of leads, the die-bonding region is at the central region, the die-bonding region comprises a metal layer, and the leads are at the peripheral region;
(b) disposing an insulation layer on the metal layer, wherein one of two ends of each of the leads is disposed on the insulation layer;
(c) providing a die, wherein the die comprises an active surface;
(d) forming a plurality of bumps on the active surface of the die;
(e) forming a solder pad on an upper surface of the end of each of the leads disposed on the insulation layer;
(f) contacting the bumps to the corresponding solder pads; and
(g) performing a reflow procedure ing so that each of the solder pads is directly soldered to a corresponding one of the bumps.

10. The manufacturing method of semiconductor device according to claim 9, wherein the bumps comprise a plurality of first bumps and a plurality of second bumps, and a height of any of the first bumps is less than a height of any of the second bumps, the solder pads comprise a plurality of first solder pads and a plurality of second solder pads, and a height of any of the first solder pads is greater than a height of any of the second solder pads.

11. The manufacturing method of semiconductor device according to claim 10, wherein in the step (f), each of the first bumps corresponds to a corresponding one of the first solder pads, and each of the second bumps corresponds to a corresponding one of the second solder pads.

12. The manufacturing method of semiconductor device according to claim 11, wherein in the step (g), each of the first solder pads is directly soldered to a corresponding one of the first bumps, and each of the second solder pads is directly soldered to a corresponding one of the second bumps.

13. The manufacturing method of semiconductor device according to claim 12, further comprising:
(h) forming a plurality of metal traces on the insulation layer, wherein each of the metal traces is coupled to one of the bumps; and
(i) disposing a capacitor on the insulation layer, wherein the capacitor is coupled between two adjacent metal traces.

14. The manufacturing method of semiconductor device according to claim 13, further comprising:
(j) forming a package to enclose the die and the lead frame.

15. The manufacturing method of semiconductor device according to claim 14, wherein the step (c) comprises:
forming a photoresist layer on the active surface of the die;
forming a plurality of first openings and a plurality of second openings on the photoresist layer, wherein the opening area of any of the first openings is smaller than the opening area of any of the second openings;
filling a metal into the first openings and the second openings;
removing the photoresist layer; and
performing a reflow procedure so that the metal in each of the first openings forms the corresponding one of the first bump and the metal in each of the second openings forms the corresponding one of the second bump.
